(19) United States
(12) Patent Application Publication
(10) Pub. No.: US 2017/0365737 A1
(43) Pub. Date: Dec. 21, 2017

(54) OPTOELECTRONIC DEVICE COMPRISING THREE-DIMENSIONAL SEMICONDUCTOR ELEMENTS AND METHOD FOR THE PRODUCTION THEREOF

(71) Applicant: Commissariat à I'Énergie Atomique et aux Énergies Alternatives, Paris (FR)

(72) Inventors: Amélie Dussaigne, Bizonnes (FR); Hubert Bono, Grenoble (FR)

(73) Assignee: Commissariat à I'Énergie Atomique et aux Énergies Alternatives, Paris (FR)

(21) Appl. No.: 15/527,031

(22) PCT Filed: Nov. 17, 2015
(86) PCT No.: PCT/FR2015/053107

§ 371 Date: May 16, 2017

(30) Foreign Application Priority Data
Nov. 24, 2014 (FR) 1461345

(51) Int. Cl. H01L 33/00; H01L 33/42; H01L 33/32; H01L 33/24; H01L 33/22; H01L 33/06; H01L 31/0216; H01L 31/18; H01L 31/0352; H01L 31/0304; H01L 31/0236; H01L 31/0224; H01L 33/44; H01L 33/08

(52) U.S. Cl. CPC H01L 33/0075; H01L 33/44; H01L 33/42; H01L 33/32; H01L 33/24; H01L 33/22; H01L 33/08; H01L 31/02161; H01L 31/1856; H01L 31/035281; H01L 31/035227; H01L 31/03044; H01L 31/02366; H01L 31/022466; H01L 33/06

(57) ABSTRACT

An optoelectronic device including a carrier having a face including flat butt-jointed facets inclined in relation to each other; seeds, mainly made of a first compound selected from the group including the compounds III-V, the compounds II-VI, and the compounds IV, in contact with the carrier in the region of at least some of the joints between the facets; and conical or frustoconical, wire-like three-dimensional semiconductor elements of a nanometric or micrometric size, mainly made of the first compound, on the seeds.

The present patent application claims the priority benefit of French patent application FR14/61345 which is herein incorporated by reference.

### BACKGROUND

The present disclosure generally relates to optoelectronic devices comprising three-dimensional semiconductor elements, for example, microwires, nanowires, conical elements, or frustoconical elements, and to methods of manufacturing the same.

Term “optoelectronic devices” is used to designate devices capable of converting an electric signal into an electromagnetic radiation or the other way, and especially devices dedicated to detecting, measuring, or emitting an electromagnetic radiation or devices dedicated to photovoltaic applications.

### DISCUSSION OF THE RELATED ART

Microwires or nanowires based on a component mainly containing a group-III element and a group-V element (for example, gallium nitride GaN), called III-V compound hereafter, or mainly containing a group-II element and a group-VI element (for example, zinc oxide ZnO), called II-VI compound hereafter, are examples of microwires or nanowires comprising a semiconductor material. Such microwires or nanowires enable to manufacture semiconductor devices such as optoelectronic devices.

Methods for manufacturing semiconductor material microwires or nanowires should enable to manufacture microwires or nanowires with an accurate and uniform control of the geometry, of the position, and of the crystallographic properties of each microwire or nanowire.

Document U.S. Pat. No. 7,829,443 describes a method of manufacturing nanowires, comprising depositing a layer of a dielectric material on a planar surface of a substrate, etching openings in the dielectric material layer to expose portions of the substrate, filling the openings with portions of a material promoting the growth of nanowires, and forming nanowires in the openings on these portions. The dielectric material is selected so that nanowires do not directly grow thereon.

In microwires or nanowires, to have the best possible properties of conversion of an electric signal into electromagnetic radiation or of electromagnetic radiation into an electric signal, it is desirable for each microwire or nanowire to have a substantially single-crystal structure. In particular, when the microwires or nanowires are mainly formed of a material based on a first element and on a second element, for example, III-V or II-VI compounds, it is desirable for each microwire or nanowire to substantially have a constant polarity all over the microwire or nanowire.

However, with the method disclosed in U.S. Pat. No. 7,829,443, the nanowire growth may be disturbed, so that each nanowire might not have a single-crystal structure. In particular, when the nanowires are mainly formed of a material based on a first element and on a second element, for example, III-V or II-VI compounds, a peripheral layer having a reverse polarity with respect to the polarity in the nanowire core may appear on the nanowire sides.

This may cause the forming of defects, especially at grain boundaries, which may alter the efficiency of the conversion of an electric signal into electromagnetic radiation or the other way.

### SUMMARY

Thus, an object of an embodiment of the present invention is to overcome at least part of the disadvantages of optoelectronic devices, particularly comprising microwires or nanowires, and of their previously-described manufacturing methods.

Another object of an embodiment of the present invention is for the three-dimensional elements, especially microwires or nanowires made of semiconductor material, not to be formed through openings made in a layer of a dielectric material.

Another object of an embodiment of the present invention is for each three-dimensional element, especially each microwire or nanowire, made of semiconductor material, to substantially have a single-crystal structure.

Another object of an embodiment of the present invention is the possibility to accurately and uniformly control the position, the geometry, and the crystallographic properties of each three-dimensional element, especially of each microwire or nanowire, made of semiconductor material.

Another object of an embodiment of the present invention is the possibility to form the three-dimensional elements, and especially the microwires or nanowires, made of semiconductor material, at an industrial scale and at low cost.

An embodiment provides an optoelectronic device comprising a support comprising a surface comprising contiguous planar facets inclined with respect to one another; seeds, mainly made of a first compound selected from the group including III-V compounds, II-VI compounds, and IV compounds, in contact with the support at at least some of the seams between facets; and three-dimensional wire-shaped, conical, or frustoconical semiconductor elements of nanometer-range or micrometer-range size, mainly made of said first compound, on the seeds.

According to an embodiment, the device further comprises, for each semiconductor element, an active region at least partially covering a portion of the semiconductor element and capable of emitting or of receiving an electromagnetic radiation.

According to an embodiment, the semiconductor elements have an elongated shape parallel to a preferred direction, and the distance, measured perpendicularly to the preferred direction, between two seeds of pairs of adjacent seeds is greater than 1 μm.

According to an embodiment, the seams comprise first raised seams and second recessed seams and the distance, measured parallel to the preferred direction, between a first seam and the second adjacent seam is greater than 1 μm.

According to an embodiment, the support comprises a substrate and at least one layer covering the substrate, the seeds being formed on said layer.

According to an embodiment, the substrate is made of a semiconductor material, particularly a substrate made of silicon, of germanium, of silicon carbide, of a III-V compound, such as GaN or GaAs, or a ZnO substrate.

According to an embodiment, the layer is made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbo-nitride (TaCN), of magnesium nitride in MgₓN_{y} form, where x is approximately equal to 3 and y is approximately equal to 2, for example, magnesium nitride in Mg₃N₂ form.

An embodiment provides a method of manufacturing an optoelectronic device, comprising the steps of:

forming a support comprising a surface comprising contiguous planar facets inclined with respect to one another;

forming seeds, mainly made of a first compound selected from the group comprising III-V compounds, II-VI compounds, and IV compounds, in contact with the support at at least some of the seams between facets; and

forming wire-shaped, conical, or frustoconical three-dimensional elements of nanometer-range or micrometer-range size, mainly made of said first compound, on the seeds.

According to an embodiment, the device further comprises, for each semiconductor element, forming an active region at least partially covering a portion of the semiconductor element and capable of emitting or of receiving an electromagnetic radiation.

According to an embodiment, the seeds are formed at a temperature in the range from 900 to 1,100° C.

According to an embodiment, the seeds are formed by metal-organic chemical vapor deposition.

According to an embodiment, the seeds are made of a III-V material and the seeds are obtained by supplying in a reactor precursors with a V/III ratio smaller than 50.

According to an embodiment, the support is made of silicon and is etched by chemical etching based on KOH or on TMAH.

### BRIEF DESCRIPTION OF THE DRAWINGS

The foregoing and other features and advantages will be discussed in detail in the following non-limiting description of specific embodiments in connection with the accompanying drawings, among which:

FIGS. 1A to 1C are partial simplified cross-section views of the structures obtained at successive steps of a known method of manufacturing an optoelectronic device comprising microwires or nanowires;

FIG. 2 is a partial simplified detail cross-section view of a microwire or nanowire obtained by the method described in relation with FIGS. 1A to 1C;

FIG. 3 is a partial simplified cross-section view of an embodiment of an optoelectronic device comprising microwires or nanowires;

FIGS. 4A to 4G are partial simplified cross-section views of the structures obtained at successive steps of an embodiment according to the invention of a method of manufacturing the optoelectronic device of FIG. 3; and

FIG. 5 is a partial simplified cross-section view of another embodiment of an optoelectronic device comprising microwires or nanowires.

### DETAILED DESCRIPTION

For clarity, the same elements have been designated with the same reference numerals in the various drawings and, further, as usual in the representation of electronic circuits, the various drawings are not to scale. Further, only those elements which are useful to the understanding of the present description have been shown and will be described. In particular, the optoelectronic device biasing and control means are well known and will not be described. In the following description, unless otherwise indicated, terms “substantially”, “approximately”, and “in the order of” mean “to within 10%”, preferably to within 5%.

In the following description, saying that a compound based on at least one first element and on a second element has a polarity of the first element and a polarity of the second element means that the material grows along a preferred direction and that when the material is cut in a plane perpendicular to the preferred growth direction, the exposed surface essentially comprises atoms of the first element in the case of the polarity of the first element or atoms of the second element in the case of the polarity of the second element.

The present application relates to optoelectronic devices comprising three-dimensional elements, for example, microwires, nanowires, conical elements, or frustoconical elements. In the following description, embodiments are described for optoelectronic devices comprising microwires or nanowires. However, such embodiments may be implemented for three-dimensional elements other than microwires or nanowires, for example, conical or frustoconical three-dimensional elements.

Term “microwire”, “nanowire”, “conical element”, or “frustoconical element” designates a three-dimensional structure having a shape elongated along a preferred direction, having at least two dimensions, called minor dimensions, in the range from 5 nm to 2.5 μm, preferably from 50 nm to 2.5 μm, the third dimension, called major dimension, being greater than or equal to 1 time, preferably greater than or equal to 5 times, and more preferably still greater than or equal to 10 times, the largest minor dimension. In certain embodiments, the minor dimensions may be smaller than or equal to approximately 1 μm, preferably in the range from 100 nm to 1 μm, more preferably from 100 nm to 800 nm. In certain embodiments, the height of each microwire or nanowire may be greater than or equal to 500 nm, preferably in the range from 1 μm to 50 μm.

In the following description, term “wire” is used to mean “microwire” or “nanowire”. Preferably, the median line of the wire which runs through the centers of gravity of the cross-sections, in planes perpendicular to the preferred direction of the wire, is substantially rectilinear and is called “axis” of the wire hereafter.

In the following description, embodiments will be described in the case of an optoelectronic device comprising light-emitting diodes. It should however be clear that these embodiments may concern other applications, particularly devices dedicated to the detection or to the measurement of electromagnetic radiation or devices dedicated to photovoltaic applications.

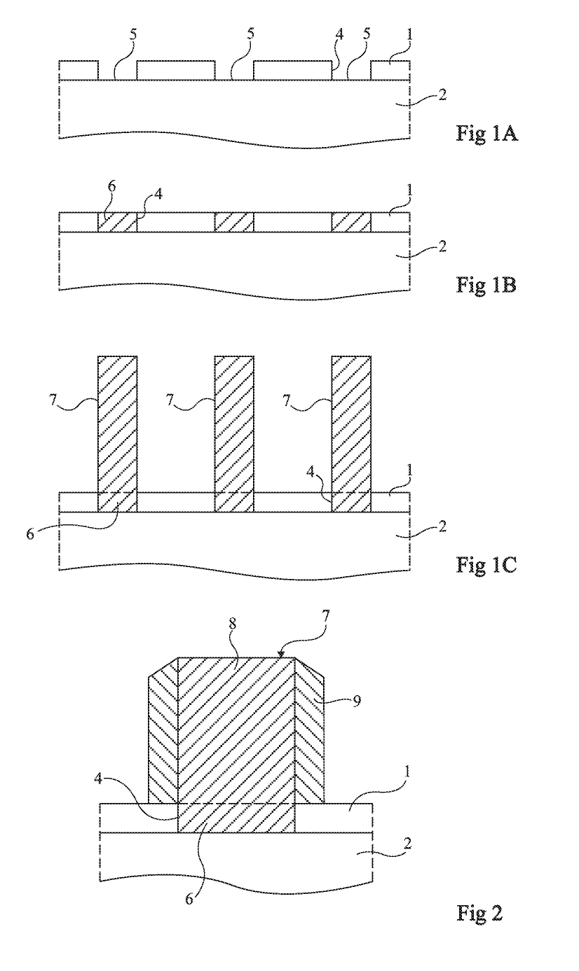

FIGS. 1A to 1C illustrate the structures obtained at successive steps of an example of a known method of manufacturing an optoelectronic device comprising wires such as previously described.

(i) A layer 1 of a dielectric material is deposited on a substrate 2 and openings 4 are etched in layer 1, openings 4 exposing certain portions 5 of substrate 2 (FIG. 1A).

(ii) Seeds 6 of a material favoring the growth of wires are grown in openings 4 (FIG. 1B).

(iii) A wire 7 is grown on each seed 6 (FIG. 1C).

FIG. 2 is a detail view of one of wires 7 shown in FIG. 1C.

The inventors have shown that when the method previously described in relation with FIGS. 1A to 1C is implemented for the forming of wires of a semiconductor material based on a compound of a first element and of a second element, this may result in the forming of a wire 7 comprising a single-crystal core 8, having the polarity of the first element, surrounded with a single-crystal peripheral layer 9 having the polarity of the second element. This may then cause the occurrence of defects at the interface between layer 9 and core 8.

An explanation would be that the presence of dielectric layer 1 disturbs the forming of seed 6 and/or the beginning of the growth of wire 7, which causes the forming of layer 9 when wire 7 grows from underlying seed 6.

According to an embodiment, before the forming of the wires, it is provided to form raised patterns on the surface of the support where the seeds forming the base of the wires should be formed. The raised patterns may particularly comprise pyramids, steps, or ribs. The support surface then comprises a succession of contiguous planar facets which are connected to one another by seams, corresponding to corners or to edges. The corners or the edges may be “raised” or “recessed”. As an example, a raised corner may correspond to the top of an asperity and a raised edge may correspond to the nosing of a step. A recessed corner may correspond to the bottom of a recess and a recessed edge may correspond to the bottom of a valley.

The inventors have shown that, when adapted growth conditions are implemented, it is possible to grow the seeds used for the forming of the wires substantially only on the raised corners or edges. The wires are thus not formed through openings provided in an insulating layer covering the support.

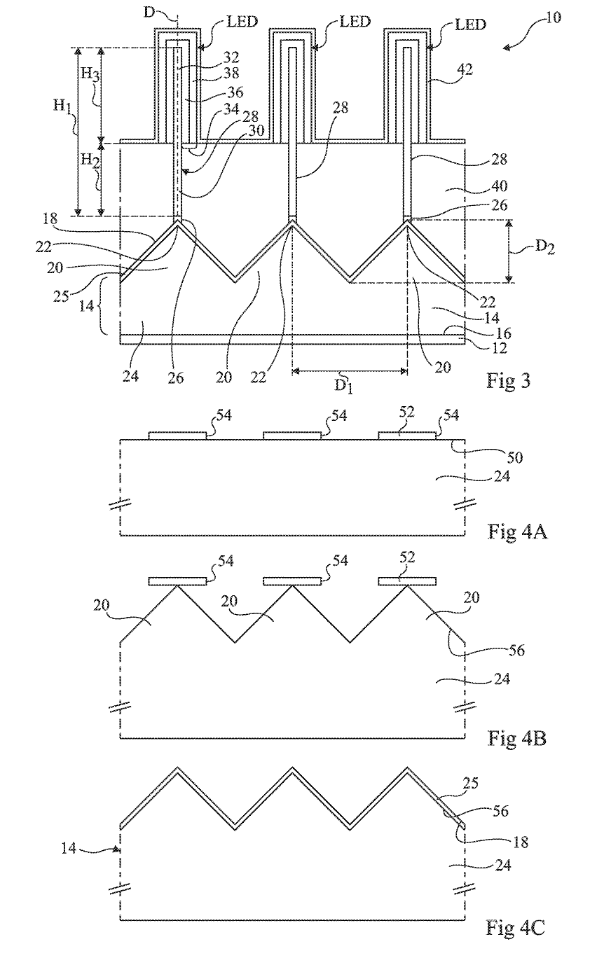

FIG. 3 is a partial simplified cross-section view of an embodiment of an optoelectronic device 10 comprising wires such as previously described and capable of emitting an electromagnetic radiation.

Device 10 comprises, from bottom to top in FIG. 3:

a first biasing electrode 12, for example, metallic;

a support 14 comprising a first surface 16 in contact with electrode 12 and a second surface 18 opposite to first surface 16, and comprising raised patterns 20, which correspond in the present embodiment to pyramids 20 each having an apex 22;

seeds 26 in contact with support 14 at apexes 22;

semiconductor elements 28 which, in the present embodiment, correspond to wires having a height H₁ and an axis D, three wires 28 being shown, each wire 28 comprising a lower portion 30 of height H₂, doped with a first conductivity type, for example, type N, in contact with one of seeds 26, and an upper portion 32 of height H₃, doped with the first conductivity type or non-intentionally doped;

a shell 34 covering the outer wall of upper portion 32 of each wire 28, each shell 34 comprising at least one stack of an active layer 36 covering upper portion 32 and of a semiconductor layer 38 of a second conductivity type opposite to the first conductivity type, covering active layer 36;

an insulating region 40 covering surface 18 between wires 28 at least along height H₂;

and a second electrode layer 42 covering the semiconductor layers 38 of shells 34 and insulating region 40.

A conductive layer, not shown, may cover electrode layer 42 between wires 28. An insulating and transparent encapsulation layer, not shown, may cover electrode 42.

The assembly formed by each wire 28 and the associated shell 34 forms a light-emitting diode LED. When a plurality of light-emitting diodes LED are formed on substrate 14, they may be connected in series and/or in parallel and form an assembly of light-emitting diodes. The assembly may comprise from a few light-emitting diodes LED to some thousand light-emitting diodes LED.

Support 14 may be a monoblock structure or may comprise a stack of one layer, of two layers, or of a plurality of layers on a substrate. In the embodiment shown in FIG. 3, support 14 comprises a substrate 24 which may be covered with a seed layer 25 capable of favoring the growth of seeds 26. Substrate 24 may be a semiconductor substrate, for example, a substrate made of silicon, of germanium, of silicon carbide, of a III-V compound, such as GaN or GaAs, or a ZnO substrate. Preferably, substrate 24 is a single-crystal silicon substrate. Preferably, it is a semiconductor substrate compatible with manufacturing methods implemented in microelectronics. Substrate 24 may correspond to a multilayer structure of silicon-on-insulator type, also called SOI. Substrate 24 may be made of an insulating material, for example, sapphire. When the structure of support 14 does not enable current to flow between surfaces 16 and 18, electrode 12 may be formed on the side of surface 18 of substrate 24. Substrate 24 may be heavily-doped, lightly-doped, or non-doped.

Seed layer 25 is made of a material favoring the growth of seeds 26. As an example, the material forming seed layer 25 may be a nitride, a carbide, or a boride of a transition metal from column IV, V, or VI of the periodic table of elements, or a combination of these compounds. As an example, seed layer 25 may be made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbide nitride (TaCN), of magnesium nitride in MgₓN_{y} form, where x is approximately equal to 3 and y is approximately equal to 2, for example, magnesium nitride in Mg₃N₂ form. Seed layer 25 may be doped with the same conductivity type as substrate 24. Seed layer 25 for example has a thickness in the range from 1 to 100 nanometers, preferably in the range from 10 to 30 nanometers.

When seed layer 25 is made of aluminum nitride, it may be substantially textured and have a preferred polarity. The texturing of seed layer 25 may be obtained by an additional treatment carried out after the deposition of seed layer 25. It for example is an anneal under an ammonia flow (NH₃). In the case of a wire 20 predominantly made of GaN, seed layer 25 may favor the growth of GaN with the N polarity.

Seeds 26 and semiconductor elements 28 are mainly formed from at least one semiconductor material selected from the group comprising III-V compounds, II-VI compounds, or group-IV semiconductors or compounds.

Seeds 26 and semiconductor elements 28 may be at least partly made of semiconductor materials mainly comprising a III-V compound, for example, a III-N compound. Examples of group-III elements comprise gallium (Ga), indium (In), or aluminum (Al). Examples of III-N compounds are GaN, AN, InN, InGaN, AlGaN, or AlInGaN. Other group-V elements may also be used, for example, phosphorus or arsenic. Generally, the elements in the III-V compound may be combined with different molar fractions.

Seeds 26 and semiconductor elements 28 may be at least partly made from semiconductor materials mainly comprising a II-VI compound. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (O) and tellurium (Te). Examples of II-VI compounds are ZnO, ZnMgO, CdZnO, CdZnMgO, CdHgTe, CdTe, or HgTe. Generally, the elements in the II-VI compound may be combined with different molar fractions.

Seeds 26 and semiconductor elements 28 may be at least partly made of semiconductor materials mainly comprising at least one group-IV compound. Examples of group-IV semiconductor materials are silicon (Si), carbon (C), germanium (Ge), silicon carbide alloys (SiC), silicon-germanium alloys (SiGe), or germanium carbide alloys (GeC).

Semiconductor elements 28 may further comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C) or an N-type group-IV dopant, for example, silicon (Si), germanium (Ge), selenium (Se), sulfur (S), terbium (Tb), or tin (Sn).

Each seed 26 has a nanometer-range average size, that is, the volume of each seed 26 is comprised within a sphere having a diameter in the range from 1 nm to 100 nm. Seeds 26 do not extend on the facets between the seams. This means that each seed 26 only covers a single seam and that there is no seed covering two or more than two seams.

Each seed 26 may correspond to a single crystal. According to the nature of the material forming seed 26 and of the material forming substrate 24 or seed layer 25 having seed 26 resting thereon, each seed 26, or at least some of them, may correspond to a quantum dot. A quantum dot is a semiconductor structure of nanometer-range dimension. It behaves as a potential well which confines electrons and holes in the three dimensions of space, in a region having a size in the order of the wavelength of electrons, that is, a few tens of nanometers in a semiconductor material.

When the three-dimensional semiconductor elements 28 of optoelectronic device 10 correspond to wires, height H₁ may be in the range from 250 nm to 50 μm. Each wire 28 may have a semiconductor structure elongated along an axis D. Axes D of wires 28 may be substantially parallel. Each wire 28 may have a cylindrical general shape with its base for example having an oval, circular, or polygonal shape, particularly triangular, rectangular, square or hexagonal. The axes of two adjacent wires 28 may be distant by from 0.5 μm to 10 μm and preferably by from 1.5 μm to 5 μm. As an example, wires 28 may be regularly dis-tributed, particularly in a hexagonal network.

According to an embodiment, the lower portion 30 of each wire is predominantly made of a III-N compound, for example, gallium nitride, doped with a first conductivity type, for example, N-type doped. The N-type dopant may be silicon. Height H₂ of lower portion 30 may be in the range from 500 nm to 25 μm.

According to an embodiment, upper portion 32 of each wire is for example at least partly made of a III-N compound, for example, gallium nitride. Portion 32 may be doped with the first conductivity type, for example, type N, or not be intentionally doped. Height H₃ of upper portion 32 may be in the range from 500 nm to 25 μm.

In the case of a wire 28 predominantly made of GaN, the crystal structure of the wire may be of wurtzite type, the wire extending along crystallographic direction c.

Active layer 36 is the layer from which most of the radiation provided by device 10 is emitted. Active layer 36 may comprise confinement means. As an example, active layer 36 may comprise a single quantum well. It then comprises a semiconductor material different from the semiconductor material forming upper portion 32 and layer 38 and having a bandgap smaller than that of the material forming upper portion 32 and semiconductor layer 38. Active area 36 may comprise multiple quantum wells. It then comprises a stack of semiconductor layers forming an alternation of quantum wells and of barrier layers.

Semiconductor layer 38 may comprise a stack of a plurality of layers especially comprising:
an electron barrier layer covering active layer 36;
an intermediate layer having a conductivity type opposite to that of lower portion 30 and covering the electron barrier layer; and
a connection layer covering the intermediate layer and covered with electrode 42.

The electron barrier layer may be formed of a ternary alloy, for example, aluminum gallium nitride (AlGaN) or aluminum indium nitride (AlInN) in contact with the active layer and the intermediate layer, to provide a good distribution of electric carriers in the active layer.

The intermediate layer, for example, P-type doped, may correspond to a semiconductor layer or to a stack of semiconductor layers and enables to form a P-N or P-I-N junction, active layer 36 being located between the intermediate P-type layer and N-type portion 32 of wire 28 of the P-N or P-I-N junction.

The bonding layer may correspond to a semiconductor layer or to a stack of semiconductor layers and enables to form an ohmic contact between the intermediate layer and electrode 42. As an example, the bonding layer may be very heavily doped, with a doping type opposite to that of lower portion 30, until degeneration of the semiconductor layer(s), for example, P-type doped at a concentration greater than or equal to 10²⁰ atoms/cm³.

Insulating region 40 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond. As an example, the thickness of insulating region 40 is in the range from 500 nm to 25 μm. Insulating region 40 may have a monolayer structure or may correspond to a stack of two layers or of more than two layers.

Electrode 42 is capable of biasing active layer 36 covering each semiconductor wire 28 and of letting through the electromagnetic radiation emitted by light-emitting diodes LED. The material forming electrode 42 may be a transparent and conductive material such as indium tin oxide (ITO), zinc oxide, doped or not with aluminum or gallium, or graphene. As an example, electrode layer 42 has a thickness in the range from 5 nm to 200 nm, preferably from 20 nm to 50 nm.

When a voltage is applied between electrodes 12 and 42, light radiation is emitted by active layer 36. Advantageously, the facets of pyramids 20 may play the role of reflective surfaces and improve the reflection of the light emitted by the active layers towards substrate 24, towards the outside of optoelectronic device 10.

The method of growing seeds 26 and/or wires 28 may be a method such as chemical vapor deposition (CVD) or metal-organic chemical vapor deposition (MOCVD), also known as metal-organic vapor phase epitaxy (MOVPE). However, methods such as molecular-beam epitaxy (MBE), gas-source MBE (GSMBE), metal-organic MBE (MOMBE), plasma-assisted MBE (PAMBE), atomic layer epitaxy (ALE), or hydride vapor phase epitaxy (HVPE) may be used.

As an example, the method may comprise injecting into a reactor a precursor of a group-III element and a precursor of a group-V element. Examples of precursors of group-III elements are trimethylgallium (TMGa), triethylgallium (TEGa), trimethylindium (TMIn), or trimethylaluminum (TMAl). Examples of precursors of group-V elements are ammonia (NH₃), tertiarybutylphosphine (TBP), arsine (AsH₃), or unsymmetrical dimethylhydrazine (UDMH). Call V/III the ratio of the gas flow of the precursor of the group-V element to the gas flow of the precursor of the group-III element.

According to an embodiment of the invention, in a phase of growth of wires 28 of the III-V compound, particularly for the growth of lower portion 30, a precursor of an additional element is added, in addition to the precursors of the III-V compound. The presence of the precursor of the additional element results in the incorporation of the additional element into the III-V compound to dope this III-V compound, but also in the forming of a layer of a dielectric material predominantly made of the additional element and of the group-V element on the lateral sides of the growing crystals of the III-V compound. The additional element may be silicon (Si). An example of a precursor of silicon is silane (SiH₄). This enables to dope the N-type wires. This may further cause the forming of a dielectric layer of silicon nitride SiN, possibly in stoichiometric form Si₃N₄, on the lateral walls of the wire. The thickness of the obtained Si₃N₄ dielectric layer is then generally smaller than 10 nm.

Surface 18 is uneven or rough, that is, it has asperities. In FIG. 3, surface 18 comprises pyramid-shaped asperities 20. Generally, surface 18 comprises a succession of contiguous facets which are connected to one another by seams, corresponding to corners or to edges, raised or recessed. In the embodiment shown in FIG. 3, the facets correspond to the surfaces of pyramids 20, the raised corners correspond to apexes 22 of pyramids 20, the recessed edges correspond to the edges located at the base of pyramids 20 and which are common with adjacent pyramids.

The inventors have shown that, when the roughness of surface 18 has specific properties and for specific growth conditions of seeds 26 described hereafter, the seeds first mainly or even totally form on some of the seams of surface 18, preferably on the raised corners, and if there are no raised corners, on the raised edges. Edges or corners 22 then form preferred growth sites for seeds 26. Seeds 26 themselves form growth sides for wires 28. An explanation would be that when the atoms of the material forming seeds 26 are deposited on surface 18 during the growth of seeds 26, these atoms tend to first accumulate at the level of the raised corners, or in the absence of raised corners, at the level of raised edges, at the level of raised edges, the locations being those where the growth of seeds 26 would require the less power.

According to an embodiment, distance D₁, measured perpendicularly to axis D, between two adjacent raised corners 22, or, in the absence of raised corners, between two adjacent raised edges, is greater than the diffusion length of the atoms of the material forming seeds 26. The diffusion length particularly depends on the geometric shape of surface 18, on its roughness, on the material forming seeds 26, and on the growth conditions of seeds 26. As an example, when seeds 26 are made of GaN, when substrate 24 is made of Si and asperities 20 correspond to pyramids, distance D₁ between two adjacent apexes 22 is in the range from 1 μm to 10 μm.

According to an embodiment, distance D₂, measured parallel to axis D, between a raised corner 22 and the adjacent recessed edge or corner 22, or, in the absence of raised corners, between a raised edge and the adjacent recessed edge or corner 22, is greater than the diffusion length of the atoms of the material forming seeds 26. As an example, when the seeds are made of GaN, when substrate 14 is made of Si and asperities 20 correspond to pyramids, distance D₂ between apex 22 and the base of pyramid 20 is in the range from 1 μm to 10 μm.

According to an embodiment, in the case where the growth of seeds 26 is achieved by MOCVD, the V/III ratio is smaller than 500, preferably smaller than 50.

The main parameter to modify the diffusion length of the material forming seeds 26 is the temperature in the reactor during the seed growth. According to an embodiment, in the case where the growth of seeds 26 is achieved by MOCVD, the temperature in the growth reactor is in the range from 900 to 1,100° C., preferably from 950 to 1,050° C.

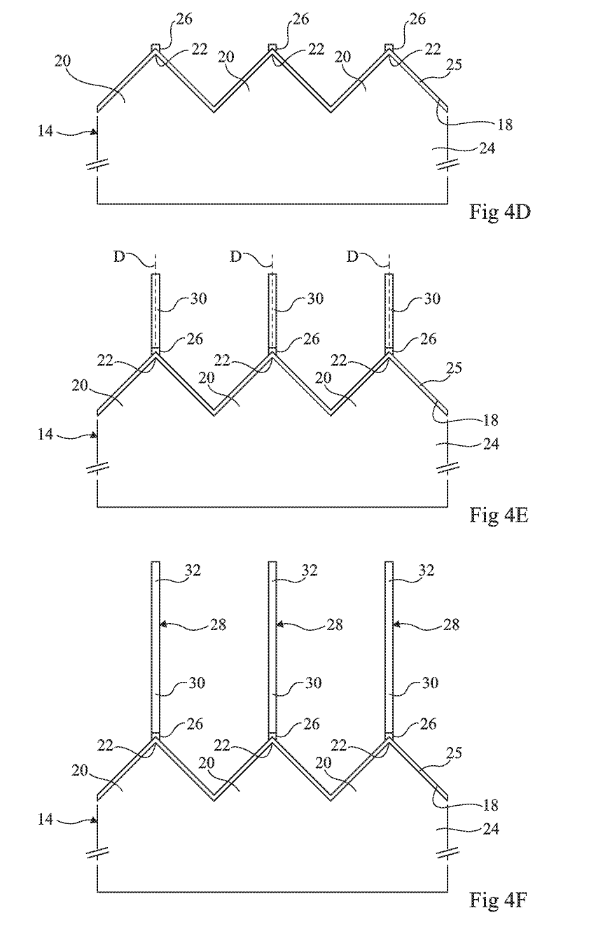

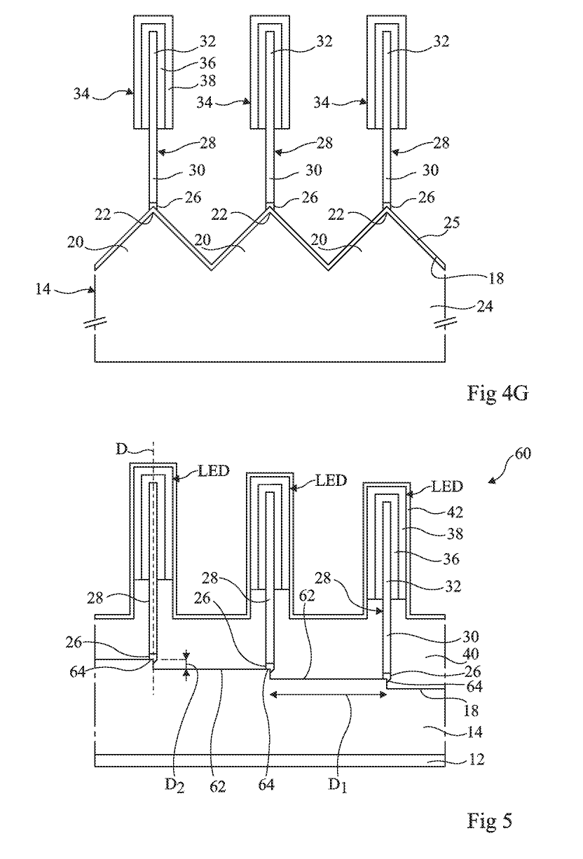

FIGS. 4A to 4G are partial simplified cross-section views of the structures obtained at successive steps of another embodiment of a method of manufacturing the optoelectronic device of FIG. 10, shown in FIG. 3.

FIG. 4A shows the structure obtained after having deposited, on a planar surface 50 of substrate 24, a layer 52, forming an etch mask, and comprising openings 54 which expose portions of surface 50 of substrate 24. Substrate 24 for example has an initial 400-μm thickness. Layer 52 for example corresponds to a layer of titanium (Ti), of titanium nitride (TiN), of silicon nitride (Si₃N₄), or of silicon dioxide (Si₂O).

According to an embodiment, layer 52 is deposited all over surface 50 and openings 54 are formed in layer 52 by etching. According to another embodiment, particularly when the layer is made of silicon nitride (SiₓN_{y}), the conditions of deposition of the layer may be adapted to cause the forming of openings 54 randomly during the deposition of layer 52.

According to another embodiment, the method of forming layer 52 comprises depositing a resin layer 52 all over surface 50 of substrate 24 and forming openings 54 in resin layer 52 by nanoimprinting lithography. Nanoimprinting lithography is an etch method where a stamp covered with a nanometer-range pattern is applied on resin layer 52. Resin layer 52 is then hardened, for example, under the effect of heat or of the exposure to ultraviolet rays, hardened resin layer 52 keeping the pattern printed from the stamp. The residual resin portion at the bottom of the printed patterns is then removed, for example, by dry etching, to obtain openings 54.

FIG. 4B shows the structure obtained after having etched substrate 24 through layer 52 to form a surface 56 comprising raised patterns and after having removed layer 52. The raised patterns may correspond to pyramids. When seed layer 25 is not present, surface 56 corresponds to previously-described surface 18. When a seed layer 25 has to be deposited, surface 56 has the same shape as the desired surface 18.

The type of etching to be used particularly depends on the material(s) forming substrate 24. According to an embodiment, in the case where the portion of substrate 24 to be etched is made of silicon, the etching of substrate 24 may be an anisotropic wet etching using an aqueous solution of potassium hydroxide (KOH) or of tetraethylammonium hydroxide (TMAH). In this case, surface 50 of substrate 24 may be a (001) surface and surface 56 obtained after the etching may be formed of (111) planes. According to an embodiment, particularly in the case where the portion of substrate 24 to be etched is made of Si, of sapphire, of SiC, of GaN, or of AlN, the etching of substrate 24 may be a directional dry etching, for example, involving a plasma. In the case where the portion of substrate 24 to be etched is made of GaN of N polarity or of AlN of N polarity, the etching of substrate 24 may be an anisotropic wet etching using an aqueous solution of potassium hydroxide (KOH).

FIG. 4C shows the structure obtained after the possible deposition of layer 25 favoring the growth of seeds 26. Seed layer 25 may be deposited by conformal deposition, for example, by MOCVD or by PVD.

FIG. 4D shows the structure obtained after the forming of seeds 26 on seed layer 25 at apexes 22 of pyramids 20. As an example, in the case where seeds 26 are made of GaN, a MOCVD-type method may be implemented by injecting into a MOCVD reactor, of shower type, a gallium precursor gas, for example, trimethylgallium (TMGa) and a nitrogen precursor gas, for example, ammonia (NH₃). As an example, a showerhead-type 3×2″ MOCVD reactor commercialized by AIXTRON, may be used. A V/III ratio smaller than 50, for example, in the range from 5 to 50, enables to favor the growth of seeds 26. The pressure in the reactor is for example in the range from 100 mbar (100 hPa) to 800 mbar (800 hPa). The temperature in the reactor is for example in the range from 900° C. to 1,100° C.

FIG. 4E shows the structure obtained after having grown lower portions 30 of wires 28. According to an embodiment, the previously-described operating conditions of the MOCVD for the growth of seeds 26 are maintained except for the fact that a silicon precursor, for example, silane (SiH₄), is added to the other precursor gases. The presence of silane among the precursor gases causes the incorporation of silicon within the GaN compound. Lower N-type doped portions 30 are thus obtained. This further results in the forming of a silicon nitride layer, not shown, which covers the periphery of each lower portion 30 except for the top, as lower portion 30 grows.

FIG. 4F shows the structure obtained after having grown upper portions 32 of wires 28. According to an embodiment, the previously-described operating conditions of the MOCVD reactor are, as an example, maintained, but for the fact that the silane flow in the reactor is decreased, for example, by a factor greater than or equal to 10, or stopped. Even when the silane flow is stopped, upper portion 32 may be N-type doped due to the diffusion in this active portion of dopants originating from the adjacent passivated portions or due to the residual doping of the GaN.

FIG. 4G shows the structure obtained after having grown shells 34 covering upper portions 32 of wires 28. The layers forming shell 34 may be formed by epitaxy. Given the presence of the silicon nitride layer covering the periphery of the lower portion 30 of each wire 28, the deposition of the layers forming shell 34 only occurs on the upper portion 32 of each wire 28.

The next steps of the embodiment of the method of manufacturing optoelectronic device 10 comprise forming insulating region 40 and forming electrodes 42 and 12. The method may comprise a step of thinning substrate 14 before the forming of electrode 12.

FIG. 5 is a partial simplified cross-section view of an embodiment of an optoelectronic device 60 comprising wires 28 such as previously described and capable of emitting an electromagnetic radiation. Optoelectronic device 60 comprises all the elements of optoelectronic device 10 previously described in relation with FIG. 3, except that pyramid-shaped patterns 20 of optoelectronic device 10 are replaced with raised step-shaped patterns 62. Further, in FIG. 5, seed layer 25 is not shown. Distance D₁, previously-described, corresponds to the distance perpendicular to axis D between two successive nosings 64 and distance D₂, previously described, corresponds to the step height, measured parallel to axis D. Nosings 64 of steps 62 form preferred growth sites for seeds 26 when the previously-described growth conditions are implemented. Raised step-shaped patterns 62 may be obtained, in particular, by dry etching and/or by the use of a misoriented substrate.

Specific embodiments have been described. Various alterations and modifications will occur to those skilled in the art. In particular, although previously-described embodiments have been described for optoelectronic devices having a radial structure where active layer 36 covers the lateral walls and possibly the top wall of upper portion 32 of the associated wire 28, the optoelectronic device may have an axial structure where the active layer is only formed in line with the wire, that is, only on the top wall of the wire.

1. An optoelectronic device comprising:
a support comprising a surface comprising contiguous planar facets inclined with respect to one another;
seeds, mainly made of a first compound selected from the group comprising III-V compounds, II-VI compounds, and IV compounds, in contact with the support at least some of the seams between facets, the volume of each seed being comprised within a sphere having a diameter in the range from 1 nm to 100 nm; and
wire-shaped, conical, or frustoconical three-dimensional elements of nanometer-range or micrometer-range size, mainly made of said first compound, on the seeds.

2. The optoelectronic device of claim 1, further comprising, for each semiconductor element, an active region at least partially covering a portion of the semiconductor element and capable of emitting or of receiving an electromagnetic radiation.

3. The optoelectronic device of claim 1, wherein the semiconductor elements have an elongated shape parallel to a preferred direction, and wherein the distance, measured perpendicularly to the preferred direction, between two seeds of pairs of adjacent seeds is greater than 1 μm.

4. The optoelectronic device of claim 3, wherein the seams comprise first raised seams and second recessed seams and wherein the distance, measured parallel to the preferred direction, between a first seam and the second adjacent seam is greater than 1 μm.

5. The optoelectronic device of claim 1, wherein the support comprises a substrate and at least one layer covering the substrate, the seeds being formed on said layer.

6. The optoelectronic device of claim 5, wherein the substrate is made of a semiconductor material, particularly a substrate made of silicon, of germanium, of silicon carbide, of a III-V compound, such as GaN or GaAs, or a ZnO substrate.

7. The optoelectronic device of claim 5, wherein the layer is made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbide nitride (TaCN), of magnesium nitride in MgₓN_{y} form, where x is approximately equal to 3 and y is approximately equal to 2, for example, magnesium nitride in Mg₃N₂ form.

8. A method of manufacturing an optoelectronic device, comprising the steps of:
forming a support comprising a surface comprising contiguous planar facets inclined with respect to one another;
forming seeds, mainly made of a first compound selected from the group comprising III-V compounds, II-VI compounds, and IV compounds, in contact with the support at least some of the seams between facets, the volume of each seed being comprised within a sphere having a diameter in the range from 1 nm to 100 nm; and
forming wire-shaped, conical, or frustoconical three-dimensional elements of nanometer-range or micrometer-range size, mainly made of said first compound, on the seeds.

9. The method of claim 8, further comprising, for each semiconductor element, forming an active region at least partially covering a portion of the semiconductor element and capable of emitting or of receiving an electromagnetic radiation.

10. The method of claim 8, wherein the seeds are formed at a temperature in the range from 900° C. to 1,100° C.

11. The method of claim 8, wherein the seeds are formed by metal-organic chemical vapor deposition.

12. The method of claim 8, wherein the seeds are made of a III-V material and wherein the seeds are obtained by supplying in a reactor precursors with a V/III ratio smaller than 50.

13. The method of claim 8, wherein the support is made of silicon and is etched by wet etching based on KOH or on TMAH.
